(19) United States
(12) Patent Application Publication
(10) Pub. No.: US 2009/0026581 A1
(43) Pub. Date: Jan. 29, 2009

(54) FLASH MEMORY DEVICE AND METHOD OF MANUFACTURING THE SAME

(76) Inventor: Jin-Ha Park, Gangnam-gu (KR)

Correspondence Address: SHERR & VAUGHN, PLLC, 620 HERNDON PARKWAY, SUITE 200, HERNDON, VA, 20170, US

(21) Appl. No.: 12/132,644

(22) Filed: Jun. 4, 2008

(30) Foreign Application Priority Data
Jul. 25, 2007 (KR) 10-2007-0074563

(51) Int. Cl. H01L 21/265; H01L 29/78; H01L 21/762

(52) U.S. Cl. 257/607; 438/525; 438/433; 257/E29.255; 257/E21.551; 257/E21.334

(57) ABSTRACT

A method includes forming trenches in a semiconductor substrate by etching the semiconductor substrate; and then forming a first ion injection layer in sidewalls of the trenches at an active region of the semiconductor substrate; and then forming a second ion injection layer in a substantially horizontally extending surface of the active region located between the trenches; and then performing a threshold voltage adjusting implant on at least the active region, wherein the first ion injection layer and the second ion injection layer overlap at a portion of the active region to provide the overlapping portion with a higher doping concentration than a non-overlapping portion of the active region; and then forming a gate structure on the active region. Since the ion doping concentration of the surface of an active area between isolation layers is totally uniform, an electric current flows uniformly through the overall surface to prevent leakage current, to improve reliability, and to prolong lifespan of the flash memory device.

The present application claims priority under 35 U.S.C. 119 to Korean Patent Application No. 10-2007-0074563 (filed on Jul. 25, 2007), which is hereby incorporated by reference in its entirety.

### BACKGROUND

A flash memory device is a non-volatile memory device capable of maintaining information stored in a memory cell even when electric power is not provided and of being electrically erased at high speed when the flash memory device is mounted to a circuit board.

A flash memory device may be configured such that a cell region as an active region defined by isolation layer 140′ in a trench as a field region and the active region has a laminated structure of a gate oxide layer, a floating gate, an interlayer dielectric, and a control gate.

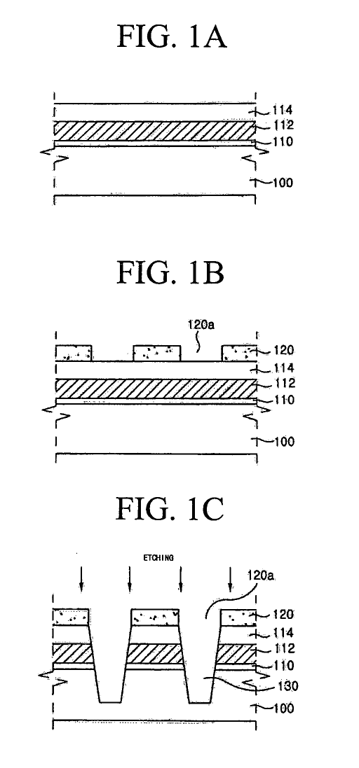

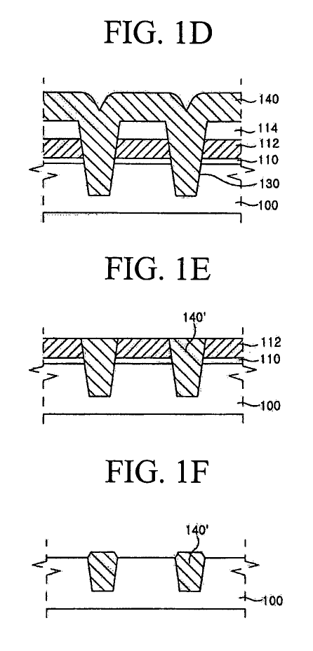

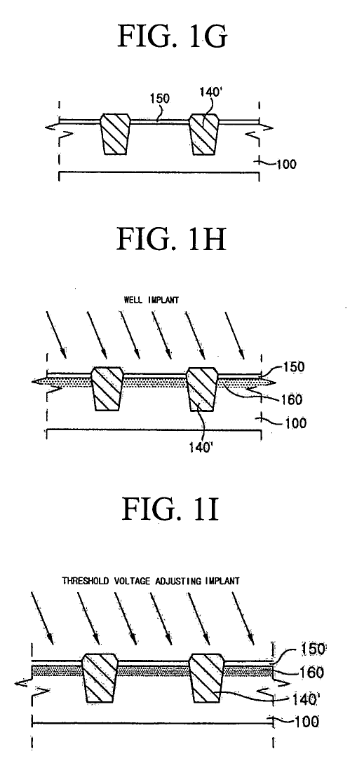

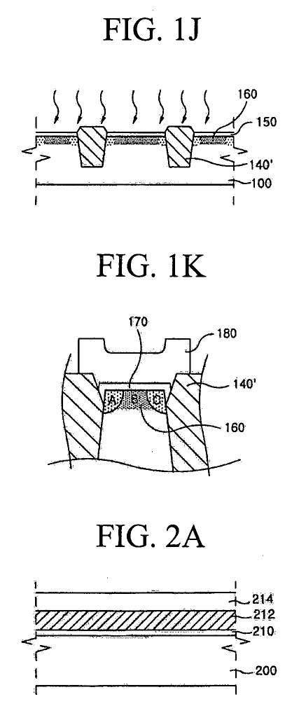

As illustrated in example FIG. 1A, a method of manufacturing a flash memory device may include sequentially laminating pad oxide 110, pad nitride 112 and pad TEOS oxide 114 on and/or over semiconductor substrate 100 made of semiconductor material such as silicon. Such lamination can be performed by deposition.

As illustrated in example FIG. 1B, in order to define an active region, photo-resist 120 having through-hole 120a for closing the active region and for opening a field region is formed on and/or over pad TEOS oxide 114 by a general photo-lithography. In this case, the photo-lithography may be carried out by sequential process of coating of photo-resist/lithography/developing.

As illustrated in example FIG. 1C, etching using an etching mask is performed to photo-resist 120 to remove portions of pad TEOS oxide 114, pad nitride 112, pad oxide 110 and semiconductor substrate 100 in the region opened by through-hole 120a of photo-resist 120 and to form depressed trench 130 in an upper side of semiconductor substrate 100. In more detail, pad nitride 112 is etched by performing the etching using photo-resist 120, and the upper side of semiconductor substrate 100 can be removed by etching using a pattern of the etched pad nitride 112, whereby slop etching with an angle of 15° to 45° can be used.

As illustrated in example FIG. 1D, insulating layer 140 such as an oxide is sufficiently embedded in trench 130.

As illustrated in example FIG. 1E, chemical-mechanical polishing is performed to partially flatten the surface of embedded insulating layer 140 until the surface of pad nitride 112 is exposed. By doing so, shallow trench isolation layer 140′ is completed through insulating layer 140 formed in trench 130, and regions other than the corresponding isolation layer 140′ is defined as the active region.

As illustrated in example FIG. 1F, wet strip is performed to pad nitride 112 and pad oxide 110 to expose the surface of the active region of semiconductor substrate 100, whereby which pad nitride 112 is removed by performing a wet etching and pad oxide 110 is removed by performing wet cleaning.

As illustrated in example FIG. 1G, oxidation is performed to form thin oxide 150 for a screen on and/or over the surface of the exposed active region of semiconductor substrate 100. Screen oxide 150 minimizes damage to semiconductor substrate 100 when a following well implant is performed.

As illustrated in example FIG. 1H, the well implant is performed to the active region of semiconductor substrate 100 to form ion injecting layer 160 in semiconductor substrate 100. The implant forms triple wells using boron ion (11B⁺).

As illustrated in example FIG. 1I, threshold voltage (Vₜₕ) adjusting implant is performed to the active region of semiconductor substrate 100 to inject threshold voltage adjusting ions into ion injecting layer 160. Although not illustrated, a photo-resist may be used as a mask to perform the implant.

As illustrated in example FIG. 1J, a thermal process is performed to re-bond the ions injected into ion injecting layer 160 within semiconductor substrate 100. The thermal process may be rapid thermal process (RTP).

As illustrated in example FIG. 1K, gate oxide 170 and floating gate 180 are properly formed on and/or over semiconductor substrate 100. Floating gate 180 is generally formed by a poly-silicon layer. After that, an interlayer dielectric and a control gate are laminated on and/or over floating gate 180 to form a laminated gate.

However, in the method of manufacturing a flash memory device has the following drawbacks. As illustrated in example FIG. 1K, both corners A and C on sides to the surface of the active region between isolation layer 140′ occupy areas that cannot be ignored in comparison to a central area B between isolation layers 140′. Thus, when the thermal process is performed, the ions (11B⁺) injected into corners A and C are diffused and escape so that doping concentration of corresponding regions is reduced less than that of the central area B. As a result, an electric current does not uniformly flow through the overall surface of the active region, even when the flash memory device is used at a later time. The electric current flows through corners A and C of low doping concentration so that increase of leakage current causes inferiority of reliability and lifespan is shortened due to concentrated current flow.

### SUMMARY

Embodiments relate to a flash memory device and manufacturing method thereof in which a pre-implant is performed to an inner wall of a trench for forming an isolation layer to inject ions into both corners of an active region so that reliability of operation can be enhanced by compensating ions diffused and leaking from the corners as heat treatment is subsequently carried out.

Embodiments relate to a flash memory device and a method of manufacturing the same which secures reliability of operation by performing a pre-implant to an inner wall of a trench in order to compensate loss of ions at corners caused by thermal processing.

Embodiments relate to a method of manufacturing a flash memory device that can include at least one of the following steps: forming a depressed trench in an upper portion of a semiconductor substrate; and then injecting ions into an active region contacting inner walls of the trench by performing a pre-implant to the inner walls of the trench; and then forming an isolation layer by embedding an insulating layer in the trench and flattening the insulating layer; and then injecting the same ions as those when the pre-implant is performed by performing a well implant to the surface of the active region of the semiconductor substrate; and then performing a threshold voltage adjusting implant to the surface of the semiconductor substrate.

Embodiments relate to a flash memory device that can include at least one of the following: a vertical ion injection layer formed in an active region of a semiconductor substrate; an isolation layer formed in the semiconductor substrate at a non-active region of the semiconductor substrate; a horizontal ion injecting layer formed in the active region substantially perpendicular to the vertical ion injection layer; and a laminated gate formed on the semiconductor substrate.

Embodiments relate to a method of manufacturing a semiconductor device that can include at least one of the following steps: forming trenches in a semiconductor substrate by etching the semiconductor substrate; and then forming a first ion injection layer in sidewalls of the trenches at an active region of the semiconductor substrate; and then forming a second ion injection layer in a substantially horizontally extending surface of the active region located between the trenches; and then performing a threshold voltage adjusting implant on at least the active region, wherein the first ion injection layer and the second ion injection layer overlap at a portion of the active region to provide the overlapping portion with a higher doping concentration than a non-overlapping portion of the active region; and then forming a gate structure on the active region. In accordance with embodiments, the semiconductor device can be a flash memory device.

### DRAWINGS

Example FIGS. 1A to 1K illustrate a method of manufacturing a flash memory device.

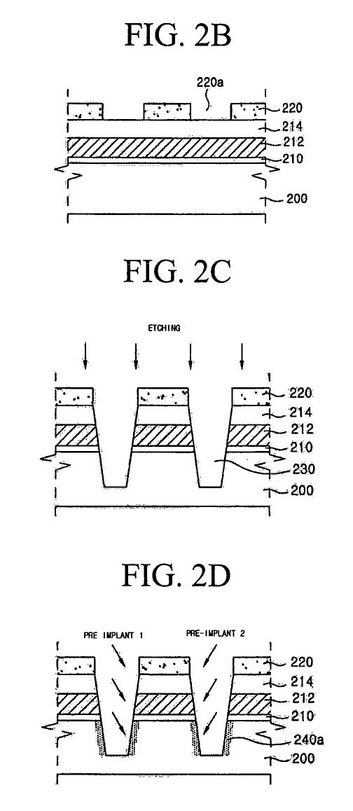

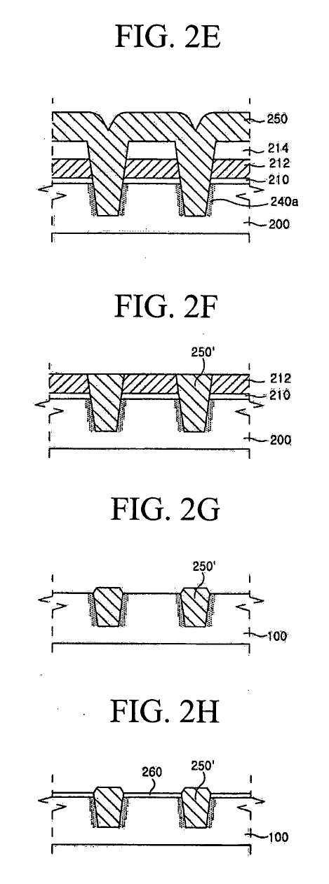

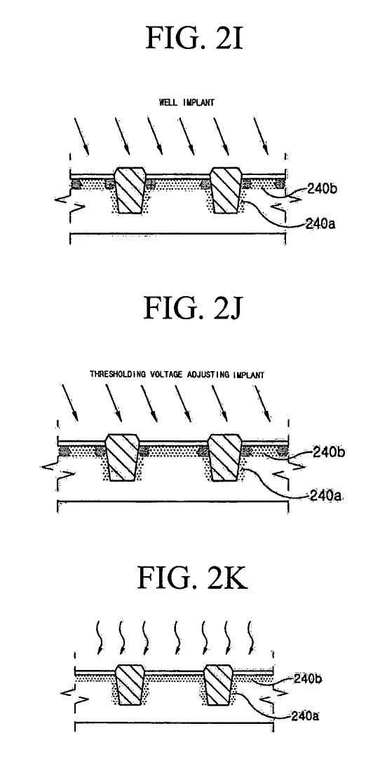

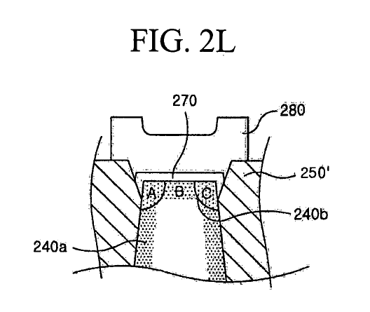

Example FIGS. 2A to 2L illustrate a method of manufacturing flash memory in accordance with embodiments.

### DESCRIPTION

As illustrated in example FIG. 2A, pad oxide 210, pad nitride 212 and pad TEOS oxide 214 may be sequentially laminated by deposition on and/or over semiconductor substrate 200 made of semiconductor material such as silicon.

As illustrated in example FIG. 2B, in order to define an active region, photo-resist 220 having through-hole 220a for closing the active region and for opening a field region is formed on and/or over pad TEOS oxide 214 by a general photo-lithography.

As illustrated in example FIG. 2C, an etching using an etching mask may then be performed to photo-resist 220 to remove portions of pad TEOS oxide 214, pad nitride 212, pad oxide 210 and semiconductor substrate 200 in the region opened by through-hole 220a of photo-resist 220 to form depressed trench 230 in an upper side of semiconductor substrate 200. Pad nitride 212 is etched initially using photo-resist 220 and semiconductor substrate 200 is etched using a pattern of etched pad nitride 212, whereby the etching may be a slope etching with an angle from between 15° to 45°.

As illustrated in example FIG. 2D, vertical ion injection layer 240a is formed by injecting into the surface of the active region contacting trench 230 by performing the pre-implant to an inclined inner sidewall of trench 230. In this case, since the pre-implant injects ions into the inclined inner sidewall of trench 230, the pre-implant must be performed at an angle by placing semiconductor substrate 200 on a stage titled at an angle between 30° to 60°. Since the pre-implant must be performed to all of the inner sidewalls of trench 230, the pre-implant is performed to the respective inner sidewall twice by rotating the stage by 0° and 180°. A corresponding implant is performed to inject the same boron ions (11B⁺) as that of a subsequent well implant with a dose higher than that of the well implant, i.e., a dose 1E14 to 1E15 ion/cm² greater than the 1E13 to 15E13 ion/cm² does of the well implant. Moreover, the injection energy is 10 KeV to 20 KeV such that ions can be injected into the sidewall of the trench to a predetermined depth.

As illustrated in example FIG. 2E, insulating layer 250 such as an oxide may can then be deposited and sufficiently embedded in trench 230.

As illustrated in example FIG. 2F, the surface of insulating layer 250, using chemical-mechanical polishing (CMP), is partially removed and flattened until the surface of pad nitride 212 is exposed. By doing so, STI isolation layers 250′ are completed through insulating layer 250 in trench 230 and regions other than a corresponding isolation layers 250′ are defined as active regions.

As illustrated in example FIG. 2G, wet strip is performed to pad nitride 212 and pad oxide 210 to expose the uppermost surface of the active region of semiconductor substrate 200, whereby pad nitride 212 is removed by performing the wet etching and pad oxide 210 is removed by performing wet cleaning.

As illustrated in example FIG. 2H, oxidation is then performed to form thin oxide layer 260 for a screen on and/or over the surface of the exposed active region of semiconductor substrate 200. Screen oxide 260 minimizes damage to semiconductor substrate 200 when a subsequent well implant process is performed.

As illustrated in example FIG. 2I, the well implant process can then be performed to the active region of semiconductor substrate 200 to form an ion injecting layer in the surface of semiconductor substrate 200. The implant forms triple wells using boron ion (11B⁺).

As illustrated in example FIG. 2J, a threshold voltage (Vₜₕ) adjusting implant can then be performed to the active region of semiconductor substrate 200. As a result, due to vertical ion injecting layer 240a formed by the pre-implant being performed in advance and horizontal ion injecting layer 240b formed by a subsequent well implant and a threshold voltage adjusting implant, both corners of the active region where vertical ion injecting layer 240a overlaps with horizontal ion injecting layer 240b has a relative higher doping concentration than the central area.

As illustrated in example FIG. 2K, a thermal process can then be performed to re-bond the ions injected into the semiconductor substrate 200 with silicon.

As illustrated in example FIG. 2L, gate oxide 270 and floating gate 280 formed by a poly-silicon layer can then be properly formed on and/or over semiconductor substrate 200. An interlayer dielectric and a control gate can then be laminated on and/or over floating gate 280 to form a laminated gate, thereby completing the method of manufacturing a flash memory device is completed.

As described above, since the pre-implant is additionally performed such that corners A and C at side surfaces of the active region has a relatively higher doping concentration than central area B, the doping concentrations of corners A and C may be the same as that of central area, even when the ions (11B⁺) of corners A and C are diffused and escape when a subsequent thermal process is performed. Therefore, the electric current can later uniformly flow and thereby prevent leakage current and guarantee reliability and a prolonged life span.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing a flash memory device comprising:
forming a trench in a semiconductor substrate; and then
injecting a first plurality of ions into a surface of an active region of the semiconductor substrate by performing a pre-implant process; and then
forming an isolation layer by forming an insulating layer in the trench and planarizing the insulating layer; and then
performing a well implant process by injecting the first plurality of ions into the surface of the active region; and then
performing a threshold voltage adjusting implant to the surface of the semiconductor substrate.

2. The method of claim 1, wherein the pre-implant process is performed by tilting the semiconductor substrate at a predetermined angle.

3. The method of claim 2, wherein the predetermined angle is between 30° to 60°.

4. The method of claim 1, wherein the pre-implant process is performed on sidewalls of the trench.

5. The method of claim 1, wherein the pre-implant process comprises injecting boron ions at a dose of between 1E14 to 1E15 ion/cm².

6. The method of claim 5, wherein the pre-implant process comprises injecting boron ions with an energy level of between 10 to 20 KeV.

7. A flash memory device comprising:
a vertical ion injection layer formed in an active region of a semiconductor substrate;
an isolation layer formed in the semiconductor substrate at a non-active region of the semiconductor substrate;
a horizontal ion injecting layer formed in the active region substantially perpendicular to the vertical ion injection layer; and
a laminated gate formed on the semiconductor substrate.

8. The flash memory device of claim 7, wherein the vertical ion injection layer and the horizontal ion injection layer overlap at a portion of the active region to provide the overlapping portion with a higher doping concentration than a non-overlapping portion of the active region.

9. The flash memory device of claim 7, wherein the vertical ion injection layer and the lateral ion injection layer are composed of boron ions implanted at a dose of between 1E14 to 1E15 ion/cm².

10. A method of manufacturing a semiconductor device comprising:
forming trenches in a semiconductor substrate by etching the semiconductor substrate; and then
forming a first ion injection layer in sidewalls of the trenches at an active region of the semiconductor substrate; and then
forming a second ion injection layer in a substantially horizontally extending surface of the active region located between the trenches; and then
performing a threshold voltage adjusting implant on at least the active region, wherein the first ion injection layer and the second ion injection layer overlap at a portion of the active region to provide the overlapping portion with a higher doping concentration than a non-overlapping portion of the active region; and then
forming a gate structure on the active region.

11. The method of claim 10, wherein forming the first ion injection layer comprises injecting ions into sidewalls of the trench.

12. The method of claim 11, wherein the ions comprise boron ions.

13. The method of claim 12, wherein the boron ions are implanted at a dose of between 1E14 to 1E15 ion/cm² and an energy level of between 10 to 20 KeV.

14. The method of claim 10, wherein forming the second ion injection layer comprises injecting ions such that the second ion injection layer extends substantially perpendicular to the first ion injection layer.

15. The method of claim 14, wherein the ions comprise boron ions.

16. The method of claim 10, further comprising, before forming the second ion injection layer and after forming the first ion injection layer: forming an isolation layer in the trench.

17. The method of claim 16, wherein forming the isolation layer comprises:
depositing an insulating layer into the trench; and then
planarizing the surface of the insulating layer.

18. The method of claim 17, wherein the isolation layers comprise shallow trench isolation layers.

19. The method of claim 10, wherein forming the trench comprises etching the semiconductor substrate using a slope etching at a predetermined angle.

20. The method of claim 10, wherein the predetermined angle is between 15° to 45°.
